(19) United States
(12) Patent Application Publication
(10) Pub. No.: US 2022/0130705 A1
(43) Pub. Date: Apr. 28, 2022

(54) ELECTROSTATIC CHUCK WITH POWDER COATING

(71) Applicant: Lam Research Corporation, Fremont, CA (US)

(72) Inventors: Jeremy George SMITH, Oakland, CA (US); Oleksandr MIKHNENKO, San Diego, CA (US); Slobodan MITROVIC, Union City, CA (US)

(21) Appl. No.: 17/429,909

(22) PCT Filed: Feb. 14, 2020
(86) PCT No.: PCT/US2020/018349

§ 371 Date: Aug. 10, 2021

Related U.S. Application Data
(60) Provisional application No. 62/809,274, filed on Feb. 22, 2019.

(51) Int. Cl. H01L 21/683; H01J 37/32; C23C 16/455; C23C 16/458; C23C 16/02

(52) U.S. Cl. CPC H01L 21/6833; H01J 37/32715; C23C 16/0272; C23C 16/4582; C23C 16/45525

(57) ABSTRACT

An electrostatic chuck (ESC) is provided. An ESC body is provided. An organic coating is disposed on at least a surface of the ESC body

### CROSS-REFERENCE TO RELATED APPLICATION

This application claims the benefit of priority of U.S. Application No. 62/809,274, filed Feb. 22, 2019, which is incorporated herein by reference for all purposes.

### BACKGROUND

The disclosure relates to a plasma processing chamber for forming semiconductor devices on a semiconductor wafer.

In the formation of semiconductor devices, plasma processing chambers are used to process the semiconductor devices. The plasma processing chamber may use an electrostatic chuck.

### SUMMARY

To achieve the foregoing and in accordance with the purpose of the present disclosure, an electrostatic chuck (ESC) is provided. An ESC body is provided. An organic coating is disposed on at least a surface of the ESC body.

In another manifestation, a method is provided. An electrostatic chuck (ESC) body is provided. An organic coating is applied on at least one surface of the ESC body.

These and other features of the present disclosure will be described in more detail below in the detailed description of the disclosure and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a cross-sectional view of an embodiment of an electrostatic chuck.

FIG. 2 is a flow chart of an atomic layer deposition of an embodiment.

FIG. 3 is a flow chart of an organic coating process of an embodiment.

FIGS. 4A-B are cross-sectional views of an electrostatic chuck in another embodiment.

FIG. 5 is a schematic view of a plasma processing chamber that may employ an embodiment.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

Materials which provide resistance to arcing are typically a metal oxide. Metal oxide is typically brittle, subject to cracking, and has relatively low coefficients of thermal expansion (CTE). Any crack induced through cycling across a wide range of temperatures will lead to electrical breakdown, causing the part to fail.

Current protective coatings on electrostatic chuck (ESC) baseplates include anodization, ceramic spray coat, or a spray coat on top of anodization. An aluminum nitride coating grown directly on the surface of aluminum baseplates is used in some products. Data show that anodization breaks down at approximately 2 kilovolts (kV) on a 0.002 inch thick coating when on a flat surface of aluminum, and at 600 volts (V) on corner radii. Spray coating, if applied normal to the surface, will withstand up to 10 kV on flat surfaces, but only about 4-5 kV on corner radii. Spray coats can be sealed with polymers, but all known effective sealing methods will degrade, when exposed to, in particular, fluorine containing plasmas under chamber operating conditions. Existing technology reaches its limits at these values since attempts to further improve the breakdown by making thicker coatings lead to cracking in response to thermal cycling, due to a mismatch between the CTE of the substrate and the CTE of coating materials.

The metal parts of an ESC can be subjected to large voltages as compared to the chamber body. Hence, it would be desirable to protect the metal parts of ESCs from chemical degradation and electrical discharge.

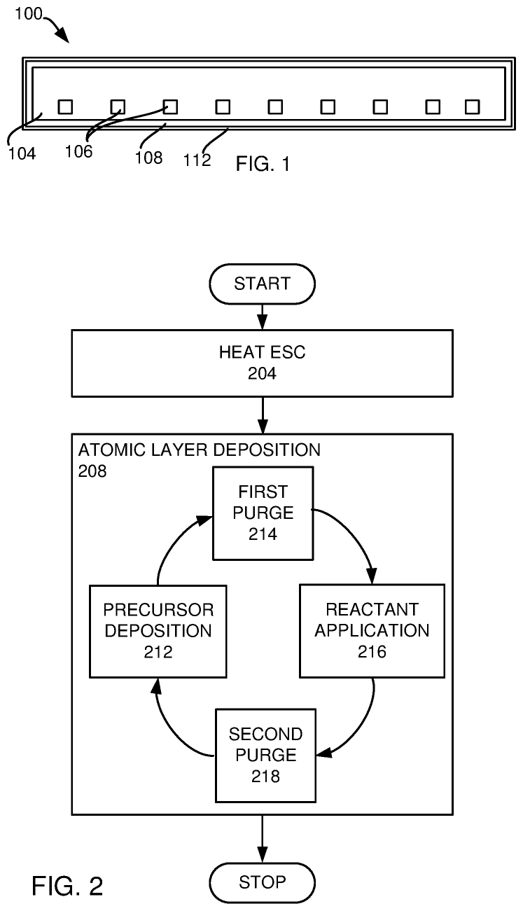

FIG. 1 is a schematic cross-sectional view of an ESC 100 according to an embodiment. The ESC 100 comprises an ESC body 104. In this example, the ESC body 104 is a base plate with cooling channels 106. In this example, the ESC body 104 is made of a conductive material. In this example, the ESC body 104 is aluminum. An organic coating 108 coats at least one surface of the ESC body 104. In one embodiment, the organic coating 108 encapsulates the ESC body 104. In this example, the organic coating 108 comprises a polymer with a metal oxide filler. In this example, the polymer is polysiloxane and the metal oxide filler is aluminum oxide nanoparticles. In this embodiment, the filler is a metal oxide nanoparticles mixed into the polymer. In this example, both the ESC body 104 and the organic coating 108 are exposed to terminal —OH (hydroxide) groups. Such exposure may be affected by chemical or plasma treatment. The organic coating 108 may be dispensed as a liquid or gel to coat at least one surface of the ESC body 104. The exposure to terminal —(OH) groups improves the adhesion of the organic coating 108. The organic coating 108 is then cured in place.

An atomic layer deposition (ALD) coating 112 coats at least one surface of the organic coating 108. In this example, the ALD coating 112 includes at least one of yttria, alumina, or yttrium aluminum garnet (YAG). FIG. 2 is a flow chart of an embodiment of applying the ALD coating 112. The ESC 100 is heated to an ALD temperature. The ALD temperature is at least the highest process temperature. The highest process temperature is the maximum temperature that the ESC 100 is expected to be subjected to during the use of the ESC 100 in a plasma processing chamber. A precursor is deposited (step 212). In this example, the precursor is trimethyl aluminum. A first purge is provided (step 214). In this example, a purge gas of N₂ is flowed to purge undeposited precursor. A reactant is applied (step 216). In this example, the reactant is water. The reactant oxidizes the aluminum to form a monolayer of alumina. A second purge is provided (step 218). In this example, a purge gas of N₂ is flowed to purge the reactant that remains as a vapor. This process is repeated for a plurality of cycles, forming the ALD coating 112.

The ESC 100 is mounted in a plasma processing chamber. The plasma processing chamber is used to plasma process substrates.

An advantage of providing the organic coating 108 of a polymer filled with a metal oxide is that the composition of both the polymer and metal oxide can be tuned readily and continuously by varying the ratio of two appropriately chosen constituents. For example, a blend of polysiloxanes and aluminum oxide nanoparticles could be created that precisely matched coefficient of thermal expansion of the ESC body 104. It is known that such materials can achieve strong adherence, given appropriate surface treatments of the ESC body 104 and the polymer of the organic coating. Such a mixture of polymer and metal oxide is inexpensive and may be mass produced. A high dielectric breakdown voltage associated with the ESC 100 may be adjusted by adjusting the thickness of the organic coating 108. The thickness of the coatings taught in the prior art may be limited by cracking when the coating becomes too thick. However, the organic coating 108 may be tailored to be not subjected to such limitations.

The ALD coating 112 protects the organic coating 108 from erosion when the ESC 100 is used for plasma processing in the plasma processing chamber. The ALD coating 112 is conformal, dense, and gas impermeable. Therefore, the ALD coating 112 seals the organic coating 108. The ALD coating 112 may be subjected to cracking during processing due to differences in the coefficients of thermal expansion between the ESC body 104 and the ALD coating 112. To eliminate or reduce cracking of the ALD coating 112, the ESC 100 is heated to an ALD temperature. The ALD temperature is at least the maximum temperature that is expected to be used during processing in the plasma processing chamber. Since the use and nonuse of the plasma processing chamber maintains the ESC 100 at a temperature below the ALD temperature, the differences in the coefficients of thermal expansion between the ESC body 104 and the ALD coating 112 maintain a compressive force on the ALD coating 112. The compressive force is caused by the coefficient of thermal expansion of the ESC body 104 being greater than the coefficient of thermal expansion of the ALD coating 112 and the temperature of the ESC 100 being less than the ALD temperature. In some embodiments, the ALD coating 112 is under compressive force at temperatures less than 20° C. In other embodiments, the ALD coating 112 is under compressive force at temperatures less than 100° C. In yet other embodiments, the ALD coating 112 is under compressive force at temperatures less than 200° C. In addition, the polymer and the metal oxide filler and the ratio of the polymer to the metal oxide filler may be selected to also reduce stress caused by the different coefficients of thermal expansion.

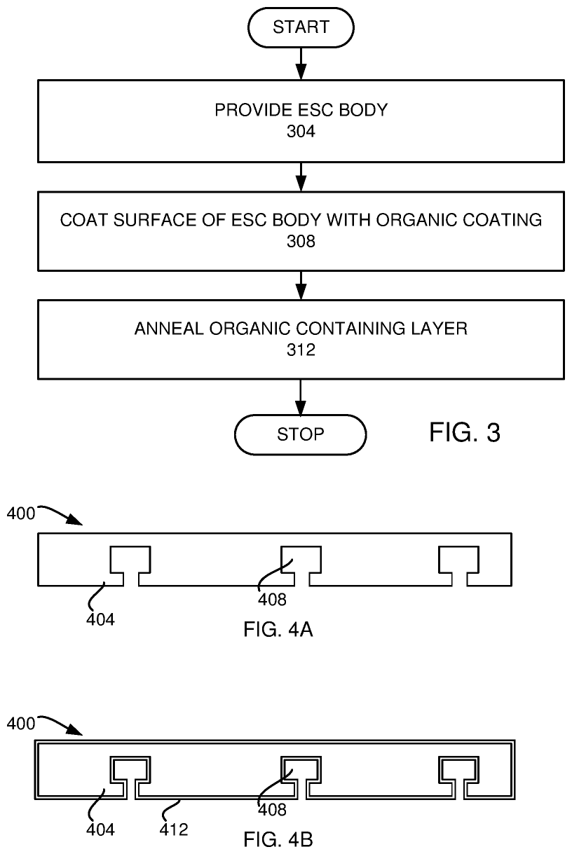

Other embodiments may not have the ALD coating. Such embodiments would have an organic coating that is resistant to plasma erosion. FIG. 3 is a flow chart of an embodiment for coating an ESC without an ALD coating. An ESC body is provided (step 304). FIG. 4A is a cross-sectional view of an ESC body 404 of an ESC 400. In this example, the ESC body 404 is aluminum. In addition, the ESC body 404 has one or more features 408. The features 408 may be cooling channels or other features formed into the ESC body 404. In this example, the features 408 have surfaces that are not in the line of sight from positions outside of the ESC body 404. The ESC body 404 is exposed to an electrostatic potential. Surfaces of the ESC body 404 are exposed to charged particles of a polymer to coat the ESC body 404 with an organic coating (step 308). In this example, the charged particles are fluoroplastic particles. The charged particles are electrostatically attracted to the surface of the ESC body 404, forming a particle coating. The charged particles of polymer are annealed to the ESC body 404 to form the organic coating (step 312). FIG. 4B is a cross-sectional view of the ESC 400 after the organic coating 412 is annealed to the ESC body 404.

This embodiment uses electrostatic potential to attract particles in order to coat surfaces with complicated geometry that cannot be coated using a line of sight deposition. In particular, corners, openings, and interior of holes can be covered using this method. In addition, various embodiments provide a more uniform layer. Various embodiments may use an electrode that may be inserted into features to increase deposition on surfaces that are not in a line of sight. The electrode does not contact the ESC body 404. Various embodiments provide an organic coating 412 with a high resistance to corrosion and high withstand voltage. In some various embodiments, the organic coating is a fluoroplastic such as polytetrafluoroethylene, polyvinylidene fluoride, polyvinyl fluoride, or polychlorotrifluoroethylene, or a fluoroelastomer, such as a copolymer of vinylidene fluoride and hexafluoropropylene, a copolymer of tetrafluoroethylene or propylene.

In other embodiments, other organic coatings may be used. For example, the organic coating may comprise polyetherimide (PEI), such as Ultem.

In other embodiments, the organic coating may comprise parylene. Parylene is a trade name for chemical vapor deposited poly(p-xylylene) polymers. In one embodiment, a conformal parylene coating is formed on a single side of an ESC body. The conformal parylene coating in this example has a high chemical resistance, except for oxygen plasma, and a very low permeability to gases and moisture, in addition to dielectric strength. If the ESC is going to be used in an oxygen plasma, an ALD coating may be applied over the parylene coating.

In other embodiments, the ALD coating may be replaced by a ceramic coating deposited by other methods. Such ceramic coating may comprise a metal oxide ceramic. In other embodiments, the organic coating may comprise one or more of a fluorinated polymer, a perfluorinated polymer, or composites of polymer and ceramic. In various embodiments, the organic coating may be treated to have a hydrophilic outer surface.

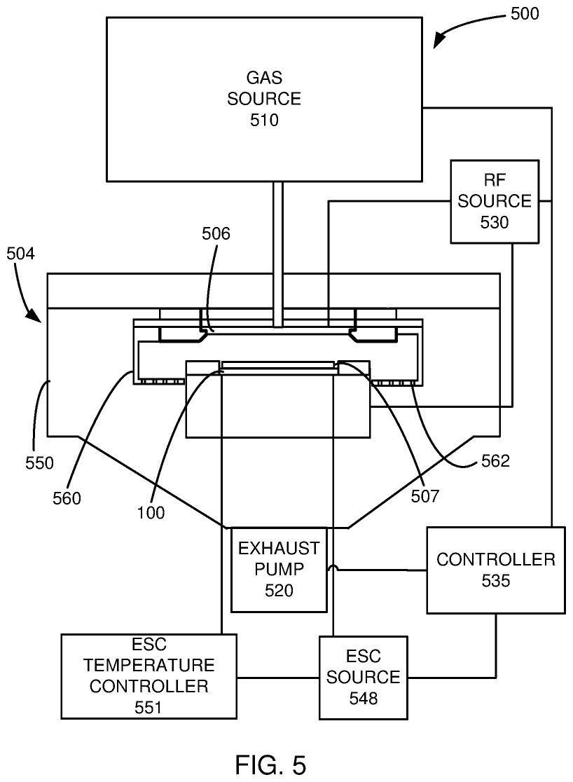

FIG. 5 is a schematic view of a plasma processing system 500 for plasma processing substrates, where the component may be installed in an embodiment. In one or more embodiments, the plasma processing system 500 comprises a gas distribution plate 506 providing a gas inlet and the ESC 100, within a plasma processing chamber 504, enclosed by a chamber wall 550. Within the plasma processing chamber 504, a substrate 507 is positioned on top of the ESC 100. The ESC 100 may provide a bias from an ESC power source 548. A gas source 510 is connected to the plasma processing chamber 504 through the gas distribution plate 506. An ESC temperature controller 551 is connected to the ESC 100 and provides temperature control of the ESC 100. A radio frequency (RF) power source 530 provides RF power to the ESC 100 and an upper electrode. In this embodiment, the upper electrode is the gas distribution plate 506. In a preferred embodiment, 13.56 megahertz (MHz), 2 MHz, 60 MHz, and/or optionally, 27 MHz power sources make up the RF power source 530 and the ESC power source 548. A controller 535 is controllably connected to the RF power source 530, the ESC power source 548, an exhaust pump 520, and the gas source 510. A high flow liner 560 is a liner within the plasma processing chamber 504. The high flow liner 560 confines gas from the gas source and has slots 562. The slots 562 maintain a controlled flow of gas to pass from the gas source 510 to the exhaust pump 520. An example of such a plasma processing chamber is the Exelan Flex™ etch system manufactured by Lam Research Corporation of Fremont, Calif. The process chamber can be a CCP (capacitively coupled plasma) reactor or an ICP (inductively coupled plasma) reactor.

The plasma processing chamber 504 is used to plasma process the substrate 507. The plasma processing may be one or more processes of etching, depositing, passivating, or another plasma process. The plasma processing may also be performed in combination with nonplasma processing. Such processes may expose the ESC 100 to plasmas containing halogen and/or oxygen.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. An electrostatic chuck (ESC), comprising:
an ESC body; and
an organic coating disposed on at least a surface of the ESC body.

2. The electrostatic chuck, as recited in claim 1, further comprising an atomic layer deposition coating disposed on the organic coating.

3. The electrostatic chuck, as recited in claim 2, wherein the organic coating comprises a polymer and a metal oxide filler.

4. The electrostatic chuck, as recited in claim 3, wherein the atomic layer deposition coating comprises a ceramic coating.

5. The electrostatic chuck, as recited in claim 3, wherein the atomic layer deposition coating comprises at least one of yttria, alumina, and YAG.

6. The electrostatic chuck, as recited in claim 3, wherein the atomic layer deposition coating is configured to operate under compressive force at temperatures less than 20° C.

7. The electrostatic chuck, as recited in claim 2, wherein the atomic layer deposition coating encapsulates the organic coating.

8. The electrostatic chuck, as recited in claim 1, wherein the organic coating comprises a polymer and aluminum oxide.

9. The electrostatic chuck, as recited in claim 1, wherein the organic coating comprises at least one of Ultem, fluorinated polymer, perfluorinated polymer, parylene, or composites of polymer and ceramic.

10. The electrostatic chuck, as recited in claim 1, wherein the organic coating comprises alumina.

11. The electrostatic chuck, as recited in claim 1, wherein the organic coating has a hydrophilic outer surface.

12. The electrostatic chuck, as recited in claim 1, wherein the organic coating encapsulates the ESC body.

13. A method comprising:
providing an ESC body; and
applying an organic coating on at least one surface of the ESC body.

14. The method, as recited in claim 13, wherein the applying the organic coating comprises:
exposing the ESC body to an electrostatic potential;
exposing the ESC body to particles, wherein the particles are electrostatically attracted to the at least one surface of the ESC body, forming a particle coating; and
annealing the particle coating.

15. The method, as recited in claim 14, wherein the particles comprise at least one of fluoroplastic and fluoroelastomer.

16. The method, as recited in claim 14, further comprising making a surface of the organic coating hydrophilic.

17. The method, as recited in claim 14, wherein the ESC body has a feature, and further comprising placing an electrode within the feature in the ESC body, wherein the electrode does not contact the ESC body.

18. The method, as recited in claim 14, further comprising coating the organic coating with an aluminum oxide containing coating.

19. The method, as recited in claim 14, further comprising depositing an atomic layer deposition coating on the organic coating.

20. The method, as recited in claim 19, wherein the organic coating includes a metal oxide filler.

21. The method, as recited in claim 14, further comprising annealing or curing the organic coating.

22. The method, as recited in claim 14, wherein the organic coating encapsulates the ESC body.

23. The method, as recited in claim 14, wherein the organic coating comprises a polymer and aluminum oxide.
